(19) United States
(12) Patent Application Publication
(10) Pub. No.: US 2009/0032964 A1
(43) Pub. Date: Feb. 5, 2009

(54) System and method for providing semiconductor device features using a protective layer

(75) Inventors: Warren Farnworth, Nampa, ID (US); Kyle Kirby, Eagle, ID (US)

Correspondence Address: FLETCHER YODER (MICRON TECHNOLOGY, INC.), P.O. BOX 692289, HOUSTON, TX, 77269-2289, US

(73) Assignee: Micron Technology, Inc.

(21) Appl. No.: 11/888,122

(22) Filed: Jul. 31, 2007

(51) Int. Cl. H01L 23/48; H01L 21/4763

(52) U.S. Cl. 257/774; 438/637; 257/E21.577; 257/E21.585

(57) ABSTRACT

Present embodiments relate to systems and methods for providing semiconductor device features using a protective layer during coating operations. One embodiment includes a method comprising providing a substrate with a hole formed partially therethrough, the hole comprising an opening in a first side of the substrate. Additionally, the method comprises disposing a protective layer over the first side of the substrate, removing a portion of the protective layer over at least a portion of the opening to provide access to the hole, and filling at least a portion of the hole with a fill material.

### BACKGROUND

1. Field of the Invention

Embodiments of the present invention relate generally to the field of semiconductor devices. More particularly, embodiments of the present invention relate to using a protective layer to provide features of a semiconductor device.

2. Description of the Related Art

Microprocessor-controlled circuits are used in a wide variety of applications. Such applications include personal computers, cellular phones, digital cameras, control systems, and a host of other consumer products. A personal computer, digital camera, or the like, generally includes various components, such as microprocessors, that handle different functions for the system. By combining these components, various consumer products and systems may be designed to meet specific needs. Microprocessors are essentially generic devices that perform specific functions under the control of software programs. These software programs are generally stored in one or more memory devices that are coupled to the microprocessor and/or other peripherals.

Electronic components such as microprocessors and memory devices often include numerous integrated circuits manufactured on a semiconductor substrate. The various structures or features of these integrated circuits may be fabricated on a substrate through a variety of manufacturing processes known in the art, including layering, doping, and patterning. It is often desirable to efficiently utilize available space on a substrate by providing planar layers that are essentially stacked on the substrate. The planar layers expand the substrate in a vertical direction relative to the plane of the substrate, thus utilizing the surface area of the substrate more efficiently. Various features or structures may be fabricated in, on, and through these layers. To electrically couple elements formed in different layers, vias may be employed. A via may be defined as a vertical opening filled with conducting material that electrically connects circuits or multiple layers of a device to each other and/or to a substrate. A via may also be filled with non-conductive material that performs various functions, such as preventing stress build up in the substrate during wafer fabrication.

Traditional procedures for fabricating die features, such as disposing conductive or non-conductive material in holes to form vias, often result in damaging existing topography (e.g., traces and pads) on or near the outermost surface of the substrate. For example, in techniques that utilize stencils to fabricate substrate features, movement of the stencil relative to the substrate may cause harmful contact between the stencil and certain topographic features on the surface of the substrate. Additionally, the material being used to form the substrate features (e.g., material being disposed in a via) may include particulate matter that can harm existing substrate topography, and traditional techniques for disposing such materials on the substrate may facilitate contact between the surface of the substrate and this harmful particulate matter. For example, certain gels that are disposed directly adjacent a substrate surface during screen printing processes may readily receive the particulate matter, thus allowing contact between the substrate surface and the particulate matter. Similarly, the particulate matter may get between a stencil and the substrate in procedures that employ stencils. Accordingly, it is now recognized that it is desirable to provide a system and method of providing semiconductor device features that limit the potential damage associated with providing such features using traditional techniques.

### BRIEF DESCRIPTION OF THE DRAWINGS

FIG. 1 illustrates a block diagram of a processor-based device in accordance with an embodiment of the present invention.

FIG. 2 is a flow diagram of a method related to the manufacture of a device in accordance with an embodiment of the present invention.

FIG. 3 is a cross-sectional view of a device including a substrate with circuitry and a redistribution layer disposed thereon in accordance with a step of one embodiment of the present invention.

FIG. 4 is a cross-sectional view of the device of FIG. 3, wherein an opening has been provided into the substrate in accordance with a step of one embodiment of the present invention.

FIG. 5 is a cross-sectional view of the device of FIG. 3 following formation of a via plate and an under bump metallization in accordance with one embodiment of the present invention.

FIG. 6 is cross-sectional view of the device of FIG. 5, illustrating the addition of a layer of material in the opening into the substrate in accordance with one embodiment of the present invention.

FIG. 7 is a cross-sectional view illustrating a protective layer disposed over the topography of the device of FIG. 6 in accordance with one embodiment of the present invention.

FIG. 8 is a cross-sectional view depicting the device of FIG. 7 after removal of a portion of the proactive layer in accordance with one embodiment of the present invention.

FIG. 9 is a cross-sectional view illustrating the device of FIG. 8 wherein a coating mechanism has disposed a fill material into a via of the device in accordance with one embodiment of the present invention.

FIG. 10 is a cross-sectional view generally illustrating removal of the protective layer and addition of a bump to the device of FIG. 9 in accordance with one embodiment of the present invention.

FIG. 11 is a cross-sectional view generally illustrating backside topography on the device in FIG. 10 in accordance with one embodiment of the present invention.

### DETAILED DESCRIPTION OF SPECIFIC EMBODIMENTS

Embodiments of the present invention generally relate to systems and methods for protecting existing features of a semiconductor device during formation of additional features on a substrate of the semiconductor device. Some embodiments of the present invention are directed to semiconductor devices that have been formed or partially formed in accordance with these systems and methods. Specifically, embodiments of the present invention relate to disposing a protective layer over a substrate to shield existing topography on a surface of the substrate from potentially damaging contact with equipment and/or materials utilized in coating operations. For example, the protective layer may serve the purpose of planarizing the surface to facilitate spreading conductive materials (e.g., solder paste) or non-conductive materials with a spreading mechanism without causing damage to existing topography. The protective layer may also serve as a barrier between the existing topography and the spreading mechanism. Further, the protective layer may seal the existing topography away from potentially harmful particulate matter in the spreading medium. Additionally, the planar nature of the protective layer may eliminate perturbations in the spreading medium due to the existing topography, which may cause distortions in the spreading equipment (e.g., distortion of a squeegee's geometry).

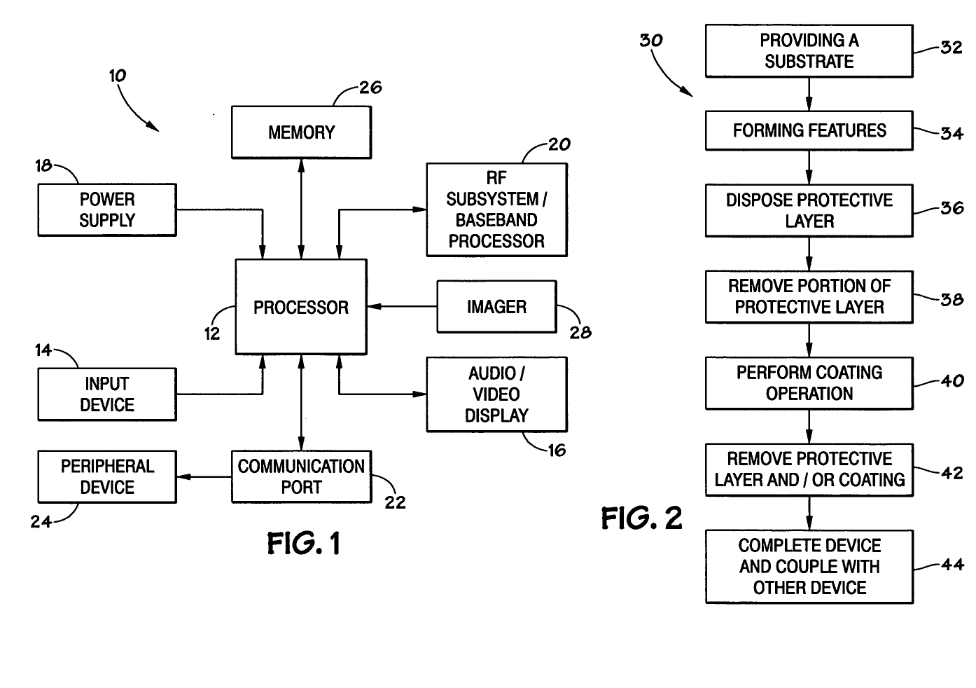

Turning now to the drawings, FIG. 1 is a block diagram of an electronic system containing integrated circuit devices that may employ embodiments of the present invention. The electronic device or system, which is generally indicated by the reference numeral 10, may be any of a variety of types, such as a computer, digital camera, cellular phone, personal organizer, or the like. In a typical processor-based device, a processor 12, such as a microprocessor, controls the operation of system functions and requests.

Various devices may be coupled to the processor 12 depending on the functions that the system 10 performs. For example, an input device 14 may be coupled to the processor 12 to receive input from a user. The input device 14 may comprise a user interface and may include buttons, switches, a keyboard, a light pen, a mouse, a digitizer, a voice recognition system, or any of a number of other input devices. An audio/video display 16 may also be coupled to the processor 12 to provide information to the user. The display 16 may include an LCD display, a CRT display, or LEDs, for example. Further, the system 10 may include a power supply 18, which may comprise a battery or batteries, a battery receptor, an AC power adapter, or a DC power adapter, for instance. The power supply 18 may provide power to one or more components of the system 10.

An RF sub-system/baseband processor 20 may be coupled to the processor 12 to provide wireless communication capability. The RF subsystem/baseband processor 20 may include an antenna that is coupled to an RF receiver and to an RF transmitter (not shown). Furthermore, a communications port 22 may be adapted to provide a communication interface between the electronic system 10 and a peripheral device 24. The peripheral device 24 may include a docking station, expansion bay, or other external component.

The processor 12 may be coupled to various types of memory devices to facilitate its operation. For example, the processor 12 may be connected to memory 26, which may include volatile memory, non-volatile memory, or both. The volatile memory of memory 26 may comprise a variety of memory types, such as static random access memory (“SRAM”), dynamic random access memory (“DRAM”), first, second, or third generation Double Data Rate memory (“DDR1”, “DDR2”, or “DDR3”, respectively), or the like. The non-volatile memory of the memory 26 may comprise various types of memory such as electrically programmable read only memory (“EPROM”) or flash memory, for example. Additionally, the non-volatile memory may include a high-capacity memory such as a tape or disk drive memory.

The system 10 may include multiple semiconductor devices. For example, in addition to the processor 12 and the memory 26, the system 10 may also include an image sensor or imager 28 coupled to the processor 12 to provide digital imaging functionality. The imager 28 may include a charge coupled device (CCD) sensor or a complementary metal oxide semiconductor (CMOS) sensor having an array of photoreceptors or pixel cells configured to be impacted by photons and to convert such impact into electrical current via the photoelectric effect. While the imager 28 may be coupled remotely from the processor 12, such as by way of a circuit board, the imager 28 and processor 12 may instead be integrally formed, such as on a common substrate.

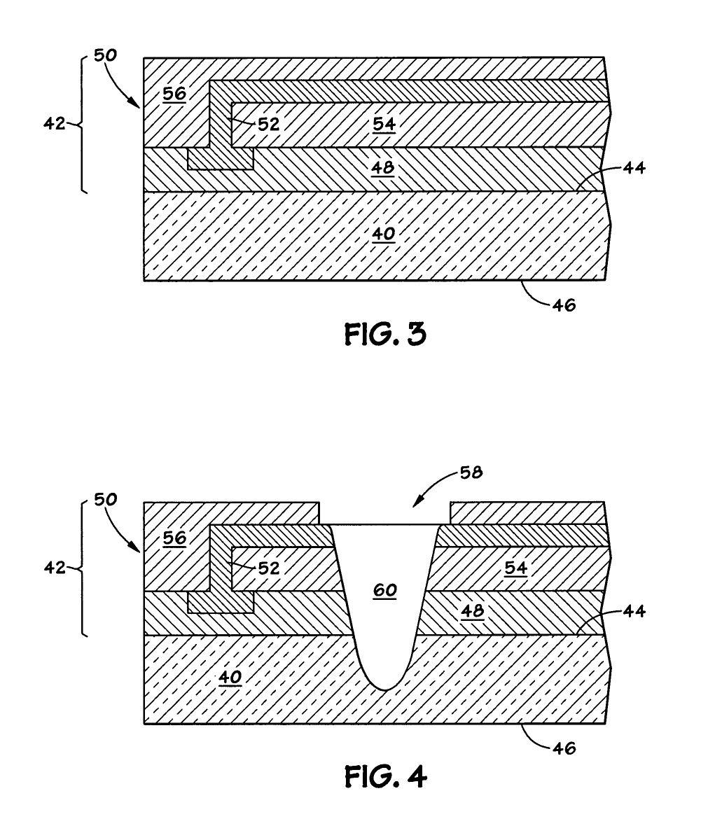

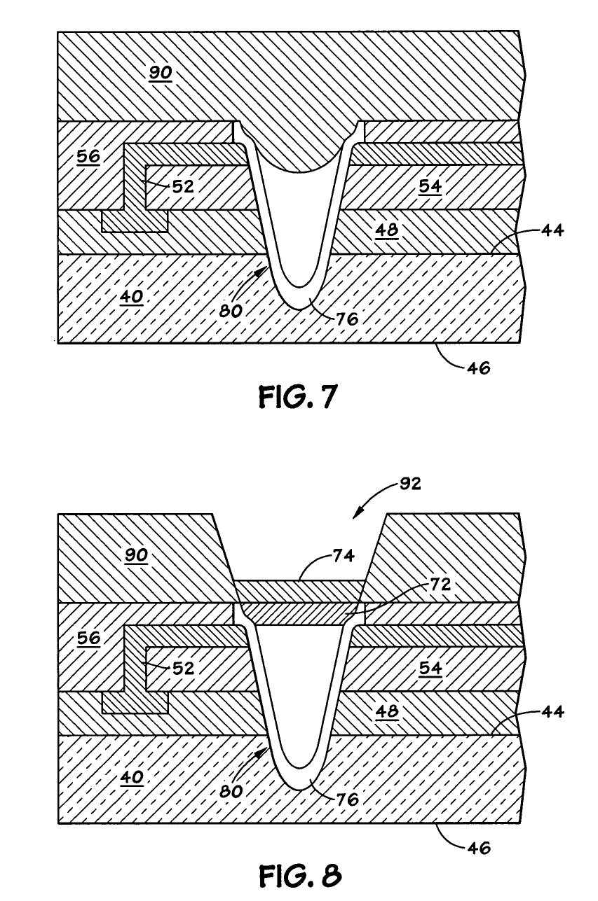

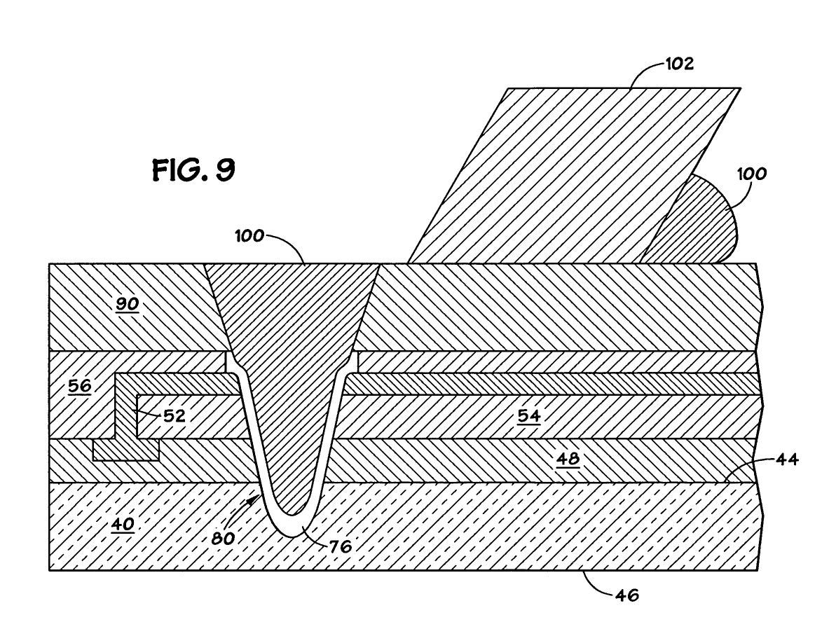

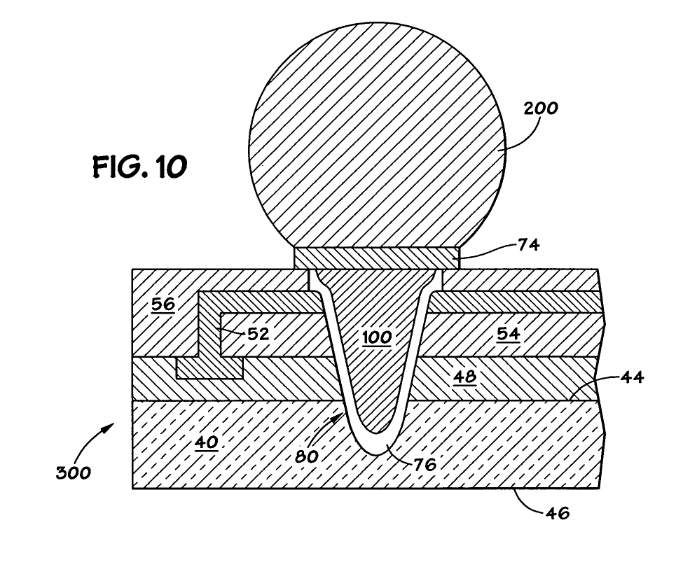

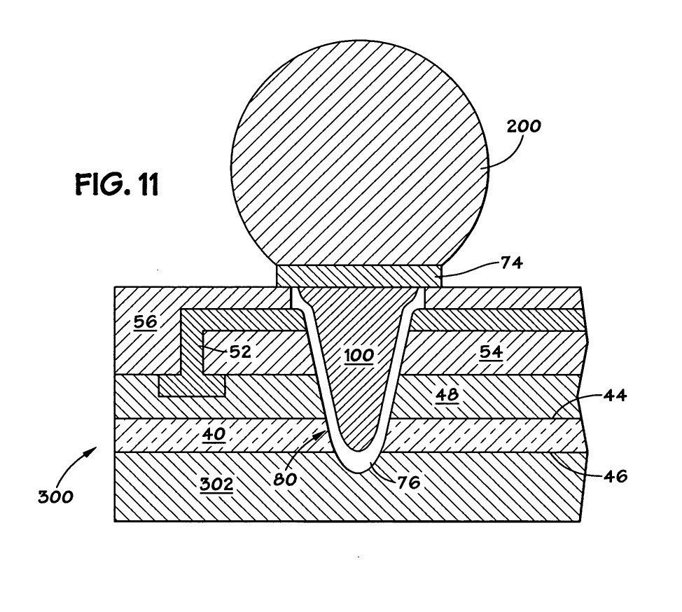

A method 30 for manufacturing a semiconductor device, such as the processor 12, the memory 26 and/or the imager 28, is generally provided in FIG. 2 in accordance with one embodiment of the present invention. Particularly, the method 30 includes a number of steps 32-44, which are described in greater detail below with respect to FIGS. 3-11. For instance, the method 30 includes a step 32 of providing a substrate and a step 34 of forming features or topography (e.g., a redistribution layer and a via) on and/or in the substrate, as generally discussed herein with respect to FIGS. 3-6. The method 30 also includes a step 36 of disposing a protective layer over the substrate and the added features, as is generally discussed below with reference to FIG. 7. Additionally, the method 30 includes a step 38 of removing (e.g., etching) a portion of the protective layer to provide limited access to features of the substrate or the substrate itself, as discussed with respect to FIG. 8. Further, the method 30 includes a step 40 of coating the protective layer with a spreader (e.g., a squeegee) such that any vias or openings in the substrate are filled with a spreading medium (e.g., solder or polymer), as discussed with respect to FIG. 9. Next, in step 42, the coating on the protective layer and the protective layer itself may be removed, as discussed with respect to FIGS. 10-11. Finally, in step 44, the various layers and features on the substrate may constitute a functional device and may be coupled to other devices, as discussed with respect to FIGS. 10-11. It should be noted that one or more of these steps of the method 30 may be performed in a reactor or processing chamber such that the environment in which the steps are performed may be regulated.

As may be provided in steps 32 and 34 of the method 30 in accordance with an embodiment of the present invention, FIG. 3 illustrates a substrate 40 with various die features 42 disposed on one side of the substrate 40. The substrate 40, which may be made of silicon or another suitable material, includes a front side 44 and a backside 46. It should be noted that the front side 44 may be designated as such because it is processed before the backside 46. For the sake of efficiency, the present technique may be implemented as a wafer-level process, in which the substrate 40 is a semiconductor wafer having numerous die regions having various features formed thereon, such as an image sensor or processor, thus facilitating simultaneous mass production of such devices 40. In other embodiments, however, the substrate 40 may be composed of other structures, such as an individual semiconductor die, in accordance with the present technique.

The die features 42 may include various layers of conductive, non-conductive, and semi-conductive material that are arranged to provide a function. For example, in the illustrated embodiment, the die features 42 include a circuitry layer 48 and a redistribution layer 50. The circuitry layer 42 may include various sub-layers of different materials that have been arranged and manipulated to form integrated circuits for a processor, a memory device, a management circuit or the like. Similarly, the redistribution layer 50 includes multiple layers that have been arranged and manipulated to provide a conductive trace 52 that communicatively couples with the circuitry layer 48 to facilitate coupling with other devices and so forth. Specifically, in the illustrated embodiment, the conductive trace 52 is formed from metal and is surrounded by non-conductive polymer layers 54 and 56.

Portions of the redistribution layer 50 may be removed (e.g., etched) to provide openings for receiving material to form traces, pads, and so forth in accordance with present techniques. For example, in the embodiment illustrated in FIG. 4, a groove 62 has been etched into a portion of the top polymer layer 56 of the redistribution layer 50 to expose the conductive trace 52. In one embodiment, the groove 58 will later be filled with conductive material to form another feature on the substrate 40, such as a trace, a via plate or a pad. Additionally, in the illustrated embodiment, aligned portions of the redistribution layer 50, the circuitry layer 48, and the substrate 40 have been removed or etched to provide an opening 60 for a via into the substrate 40. Vias may be included in a semiconductor device to perform any of various functions. For example, depending on the type of material disposed or grown in the via, the via may serve as a communicative coupling or to prevent stress build up in the substrate 40 during fabrication.

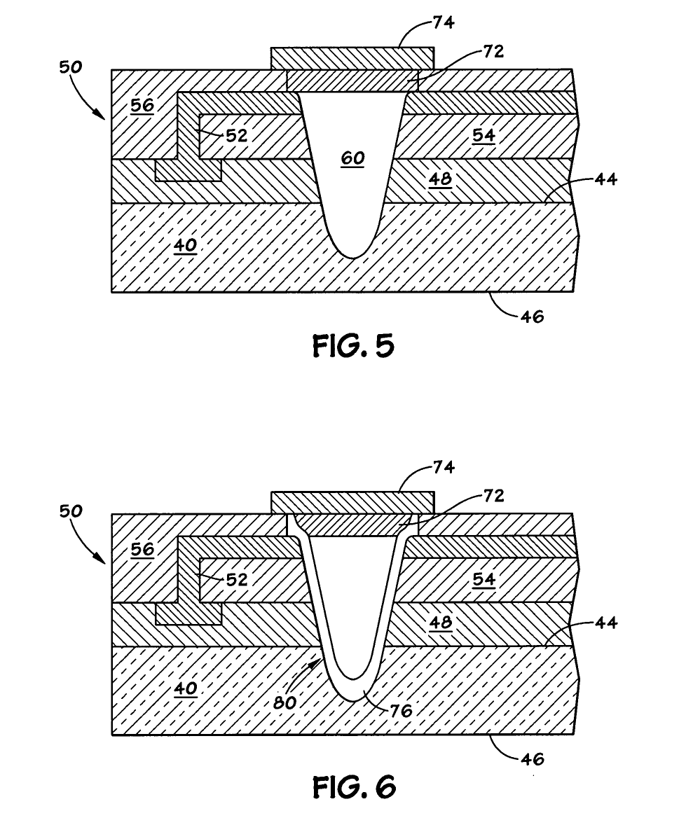

As illustrated in FIG. 5, the groove 58 may be filled with a conductive material in accordance with present embodiments. Specifically, in the embodiment illustrated by FIG. 5, the groove 58 has been filled with the conductive material to form a via plate 72. Further, the via plate 72 is covered with an under bump metallization (UBM) 74 that is configured to receive a bump (e.g., a solder ball) or the like to facilitate directly or indirectly coupling with other devices (e.g., a memory or an imager). These features may be added through any of various procedures known in the art. Additionally, as illustrated in FIG. 6, a layer of material 76 may be disposed along the interior walls of the opening 60 by any of various deposition processes to establish a via 80. The layer of material 76 may include any of various types of material (e.g., conductive material, insulation, or flexible material) depending on the desired function for the via 80. If during such a deposition process, the layer of material 76 is disposed outside of the opening 60 (e.g., on a surface of the redistribution layer 50), it may be removed with an etching process or the like.

All of the added features on the substrate 40, such as the redistribution layer 50, the via 80, the via plate 72, the UBM 74 and so forth may be generally referred to as topography. FIG. 7 illustrates a protective layer 90 disposed over the topography of the substrate 40, as may be provided in step 36 of the method 30 in accordance with present embodiments. The protective layer 90 may initially fill a portion of the via 80, as illustrated in FIG. 7. However, as may be provided in step 38 and as illustrated in FIG. 8, a portion of the protective layer 90 above the via 80 may be removed to expose an opening 92 through the protective layer 90 and into the via 80 in accordance with present embodiments. During this removal process (e.g., etching), any portion of the protective layer 90 that extended into the via 80 will also be removed. It should be noted that having the protective layer 90 in place over the topography protectively seals the topography away from potentially harmful substances and shields the topography from spreading equipment that may be utilized to fill the via 80 with a desired material, as discussed in further detail below.

As illustrated in FIG. 9, once the protective layer 90 is in place over the topography of the substrate 40, it may be used essentially as a stencil in a coating operation, as indicated by step 40 in accordance with present embodiments. Specifically, as illustrated in FIG. 9 a fill material 100 (e.g., solder or polymer) may be pushed into the via 80 through the opening 92 in the protective layer 90 by a coating device 102. In the illustrated embodiment, the coating device 102 is a squeegee. However, in other embodiments the coating device 102 may include any of various devices that pass over the protective layer 90 and press or inject the fill material 100 into openings (e.g., opening 92) therein. For example, in some embodiments, the coating device 102 may include a print head, a pressurized head, or the like.

It should be noted that prior to moving the coating device 102 across the protective layer 90, the protective layer 90 may be planarized to facilitate passage of the coating device 102 over the protective layer 90 with little resistance. For example, planarization of the protective layer 90 may be achieved by wearing down inconsistencies on the outer portion of the protective layer 90 with a wet polish pad or the like. This may prevent the creation of artifacts in the fill material 100 resulting from distortion of the coating device 102, which could be caused by substantially uneven contact between the coating device 102 and the protective layer 90. For example, a squeegee may flex or bend while passing over the protective layer 90 if one side of the squeegee passes over a high point of the protective layer 90 while another side passes over a low point. Such distortion may cause a disruption in the even distribution of the fill material 100.

As set forth in step 42 of method 30, once the via 80 has been filled with the fill material 100, the protective layer 90 may be removed in accordance with an embodiment of the present invention. For example, this may be achieved with an etching process that utilizes a specific etching chemical for the specific type of material used to form the protective layer 90. Similarly, the portion of the fill material 100 residing in the opening 92 in the protective layer 90 may be removed by etching. For example, FIG. 10 illustrates the substrate 40 and its topography after removal of the protective layer 90 and the excess fill material 100 that extended into the opening 92 in the protective layer 90. Once the protective layer 90 is removed, the UMB 74 is exposed and a contact bump 200 may be coupled to the surface of the UBM 74. The contact bump may be formed of any suitable, electrically conductive material, such as solder. Notably, the contact bump 200 facilitates direct coupling to other circuitry. For example, in one embodiment, the contact bump 200 may enable direct coupling with a socket in a circuit board or allow electrical communication between features of the substrate 40 and external electronic devices, as set forth in step 44 of method 30 in accordance with present embodiments.

The various layers and features on the substrate 40 may eventually constitute a functional device 300 (e.g., a memory or processor). Indeed, some functionality may be provided on the backside 46 of the device 300. For example, as illustrated in FIG. 11, the back side 46 of the substrate 40 may be modified to include backside topography 302. This modification may include etching or grinding away a portion of the substrate 40 and disposing backside topography 302 thereon. As with the provision of the features of the front side, the backside topography 302 may be formed through any suitable combination of processes. For instance, in one embodiment, portions of the backside topography 302 are spun-on to the substrate 40 and patterned to form particular features. For example, in one embodiment, patterning may include applying a photoresist layer to a passivation layer, then exposing and developing the photoresist layer to form trenches that can be filled with conductive material to define vias, and so forth. Further, in other embodiments, forming the backside topography may include grinding and/or polishing processes designed to wear away layers and expose previously disposed features. It should be noted that during backside processing, a protective layer similar to that used on the front side may also be employed.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. A method comprising:
forming a via through one or more layers;
disposing a protective layer on a top surface of the one or more layers;
filling the via; and
removing the protective layer.

2. The method of claim 1, comprising removing a portion of the protective layer over the via.

3. The method of claim 1, wherein filling the via comprises injecting or pressing material into the via.

4. The method of claim 3, wherein the material comprises a flexible material.

5. A method comprising:
providing a substrate with a hole formed partially therethrough, the hole comprising an opening in a first side of the substrate;
disposing a protective layer over the first side of the substrate;
removing a portion of the protective layer over at least a portion of the opening to provide access to the hole; and
filling at least a portion of the hole with a fill material.

6. The method of claim 5, wherein the substrate comprises a semiconductor wafer.

7. The method of claim 5, comprising disposing an insulation layer along walls of the hole prior to filling the portion of the hole with the fill material.

8. The method of claim 5, comprising disposing a conductive layer along walls of the hole prior to filling the portion of the hole with the fill material.

9. The method of claim 5, wherein the fill material comprises a conductive material.

10. The method of claim 5, wherein the fill material comprises solder.

11. The method of claim 5, wherein the fill material comprises a flexible material.

12. The method of claim 5, wherein filling the portion of the hole with the fill material comprises forcing the fill material into the hole with a squeegee.

13. The method of claim 5, wherein filling the portion of the hole with the fill material comprises forcing the fill material into the hole with a dispenser.

14. The method of claim 5, comprising removing a portion of the substrate from a second side of the substrate opposite the first side to expose the fill material.

15. The method of claim 5, comprising attaching the substrate to a system board.

16. The method of claim 5, comprising providing the substrate with a distribution layer and a circuitry layer disposed thereon.

17. The method of claim 5, comprising communicatively coupling the substrate to an electronic device via a bump communicatively coupled to a circuitry layer of the substrate.

18. The method of claim 5, comprising processing a second side of the substrate opposite the first side to provide backside topography.

19. A method, comprising:
providing a substrate comprising features on and in the substrate;
disposing a protective layer over the substrate and the features;
removing a portion of the protective layer over one or more of the features in the substrate; and
performing a coating operation over the protective layer, wherein a coating mechanism contacts the protective layer and pushes fill material into the one or more features in the substrate.

20. The method of claim 19, comprising removing the protective layer after the coating operation.

21. The method of claim 19, comprising communicatively coupling the substrate to an electronic device.

22. An structure, comprising:
a substrate comprising a plurality of features formed in and on the substrate;
a protective layer disposed over the features; and
an opening formed through the protective layer into at least one of the features formed in the substrate.

23. The structure of claim 22, comprising a fill material disposed in the opening and in the at least one feature.

24. The structure of claim 23, wherein the protective coating comprises a polymer and the fill material comprises insulation.
